(19) United States
(12) Patent Application Publication
(10) Pub. No.: US 2018/0145668 A1
(43) Pub. Date: May 24, 2018

(54) VOLTAGE CLAMPING CIRCUIT

(71) Applicant: Mosway Technologies Limited, Hong Kong (CN)

(72) Inventor: On Bon Peter CHAN, Hong Kong (CN)

(21) Appl. No.: 15/817,368

(22) Filed: Nov. 20, 2017

Related U.S. Application Data
(60) Provisional application No. 62/425,171, filed on Nov. 22, 2016.

(51) Int. Cl. H03K 5/08; H03K 17/687

(52) U.S. Cl. CPC H03K 5/08; H03K 2217/0072; H03K 2217/0063; H03K 17/6872

(57) ABSTRACT

A voltage clamping circuit for a driver arranged to drive a half bridge circuit connected to an inductive load. The circuit includes a detector arranged to detect magnitude of a voltage at a switched node connected to the inductive load and to provide an input signal indicative of the magnitude of the voltage at the switched node; and a comparator arranged to receive and compare the input signal to a reference signal representing a reference voltage value, for selectively controlling operation of a switching device to clamp the voltage at the switched node thereby reducing the magnitude of the voltage at the switched node.

### TECHNICAL FIELD

The invention relates to a voltage clamping circuit and particularly, although not exclusively, to a negative transient voltage clamping circuit for use in a driver of a half bridge circuit.

### BACKGROUND

FIG. 1 shows a conventional half-bridge driver 100. The driver 100 is arranged to receive a high-side input HIN and a low-side input LIN, for controlling a high-side output HO and a low-side output LO respectively. The low-side output LO can change between voltage levels COM and VCC. The potential of COM may be at ground (zero V) and the potential of VCC may be 20V. The high-side output HO can change between the floating voltage levels VS and VB, where |VB-VS| is the magnitude of the power supply for the high side circuit similar to |VCC-COM| is the magnitude of the power supply voltage for the low side circuit. VS is a floating voltage with reference to COM which can switch between a low voltage below COM and very high voltage above COM (e.g. 600V). The high-side output HO and the low-side output LO are each arranged to drive a respective power switch 150, 152 which is further connected to a load. As shown in FIG. 1, the driver 100 includes an input logic module arranged to receive the high-side input HIN and the low-side input LIN. The input logic module is connected with a low-side circuit providing the low-side output LO and a high-side circuit providing the high-side output HO.

The low-side circuit includes a first path with an under-voltage lockout (UVLO) module connected with VCC, and a second path with a delay module and a buffer module. A low-side driver module formed by two switches is connected across VCC and COM. More particularly, the buffer module is connected with the gate terminals of both switches. The drain terminals of the switches are connected to the low-side output LO.

The high-side circuit includes a pulse generator connected with the input logic module and arranged to receive a signal processed by the input logic module. The pulse generator is connected with a level shifting circuit with two switches 101, 102 (e.g., high voltage LDMOS devices) at their gate terminals. Source terminals of the two switches 101, 102 are connected together and to COM. The drain terminal of one switch 101 is connected with a RB node that is connected with a pulse filter 105 and an R̅ terminal of a RS latch 180. The drain terminal of the other switch 102 is connected with a SB node that is connected with the pulse filter 105 and an S̅ terminal of the RS latch 180. The level shifting circuit also includes a resistor 170 arranged between the RB node and VB, and a resistor 172 arranged between the SB node and VB. A buffer module 106 and a high-side driver module with two switches 107, 108 are connected between the output Q̅ of the RS latch 180 and the high-side output HO. An under-voltage lockout (UVLO) module 109 is connected between the input R of the RS latch 180 and VB. The drain terminals of the switches 107, 108 are connected with the high-side output HO.

A half bridge circuit is connected at the output of the half-bridge driver 100. The half bridge circuit includes, among other components, a high side power switching device (e.g., MOSFET) 150 arranged to be driven by the high-side output HO and a low side power switching device (e.g., MOSFET) 152 arranged to be driven by the low-side output LO. An inductive load, in the form of an inductor 154 in this example, is connected to the half bridge circuit, at VS (“switched node”) between the high side power switching device 150 and the low side power switching device 152.

During operation of the circuit in FIG. 1, when the high side power switching device 150 is turned off, the switched node VS may become negative as the inductor 154 attempts to maintain its current. Hence, current will flow through a body diode (not shown) of the low side power switching device 152 between the COM and VS nodes, creating a negative transient voltage at the VS node. Such negative transient voltage may, in practice, often be more negative than just a forward diode's voltage drop, due to the parasitic inductance in the interconnecting trace in the PCB as well as the wiring. If the magnitude of such a transient voltage is too large (i.e., the transient voltage is too negative), it may cause malfunction of the circuit or even damage the circuit.

### SUMMARY OF THE INVENTION

In accordance with a first aspect of the invention, there is provided a voltage clamping circuit for a driver arranged to drive a half bridge circuit connected with an inductive load, comprising: a detector arranged to detect a magnitude of a voltage at a switched node connected with the inductive load and to provide an input signal indicative of the magnitude of the voltage at the switched node; and a comparator arranged to receive and compare the input signal with a reference signal representing a reference voltage value, for selectively controlling operation of a switching device to clamp the voltage at the switched node and reduce the magnitude of the voltage at the switched node. The input signal indicative of the magnitude of the voltage at the switched node can be a voltage signal directly representing (with the same value as) the magnitude of the voltage at the switched node, or it may be a voltage signal indirectly (scaled, offset, etc.) representing the magnitude of the voltage at the switched node.

Preferably, the comparator is arranged to turn on the switching device (e.g., closes a switch) when the comparison indicates that the magnitude of the voltage exceeds the reference voltage value, and to turn off the switching device (e.g., opens a switch) when the comparison indicates that the magnitude of the voltage falls below the reference voltage value.

The reference signal may be adjustable to represent a different reference voltage value; or it may be fixed to represent a predetermined reference voltage value.

Preferably, the detector comprises a diode and a resistor. The diode may be an emulated diode emulated by a semiconductor device.

Preferably, the voltage clamping circuit further comprises the switching device.

The switching device may comprise a semiconductor switch, e.g., in the form of a MOSFET or a bi-polar transistor.

Preferably, the voltage clamping circuit further comprises a current-limiting resistor connected in series with the switching device.

Preferably, the switching device is part of the driver or the half bridge circuit.

Preferably, the detector comprises a scaling circuit to scale the detected magnitude of the voltage at the switched node to provide the input signal.

Preferably, the half bridge circuit comprises a high-side switching device and a low-side switching device, and the switched node is arranged between the high-side switching device and the low-side switching device.

Preferably, the voltage clamping circuit is a negative transient voltage clamping circuit and the detector is arranged to detect a magnitude of a negative transient voltage at the switched node.

In accordance with a second aspect of the invention, there is provided a voltage clamping method adapted for a driver arranged to drive a half bridge circuit connected with an inductive load, comprising: detecting a magnitude of a voltage at a switched node connected with the inductive load and to provide an input signal indicative of the magnitude of the voltage at the switched node; and comparing the input signal with a reference signal representing a reference voltage value to selectively control operation of a switching device so as to clamp the voltage at the switched node and to reduce the magnitude of the voltage at the switched node.

Preferably, the method further comprises turning on the switching device when the comparison indicates that the magnitude of the voltage exceeds the reference voltage value, and turning off the switching device when the comparison indicates that the magnitude of the voltage falls below the reference voltage value.

Preferably, the method further comprises scaling the detected magnitude of the voltage at the switched node to provide the input signal.

The method in the second aspect of the invention may be implemented using the voltage clamping circuit of the first aspect.

In accordance with a third aspect of the invention, there is provided a non-transitory computer readable medium for storing computer instructions that, when executed by at least one controller or processor, causes at least one controller or processor to perform a voltage clamping method adapted for a driver arranged to drive a half bridge circuit connected with an inductive load, the method comprising: detecting a magnitude of a voltage at a switched node connected with the inductive load and to provide an input signal indicative of the magnitude of the voltage at the switched node; and comparing the input signal with a reference signal representing a reference voltage value to selectively control operation of a switching device so as to clamp the voltage at the switched node and to reduce the magnitude of the voltage at the switched node.

The non-transitory computer readable medium in the third aspect of the invention may be arranged to cause at least one controller or processor to perform the method of the second aspect.

### BRIEF DESCRIPTION OF THE DRAWINGS

Embodiments of the invention will now be described, by way of example, with reference to the accompanying drawings in which:

FIG. 1 is a circuit diagram of a typical driver for a half bridge circuit, with which the voltage clamping circuit in accordance with the invention can be operated;

FIG. 2 is a functional block diagram illustrating the operation principle of the voltage clamping circuit in accordance with the invention;

FIG. 3 is a circuit diagram of a voltage clamping circuit in accordance with one embodiment of the invention;

FIGS. 4A is a circuit diagram of an alternative detector that may be used in the voltage clamping circuit of FIG. 3;

FIGS. 4B is a circuit diagram of an alternative detector that may be used in the voltage clamping circuit of FIG. 3;

FIG. 5A is a circuit diagram of a voltage clamping circuit in accordance with another embodiment of the invention; and

FIG. 5B is a circuit diagram of a voltage clamping circuit in accordance with yet another embodiment of the invention.

### DETAILED DESCRIPTION OF THE PREFERRED EMBODIMENT

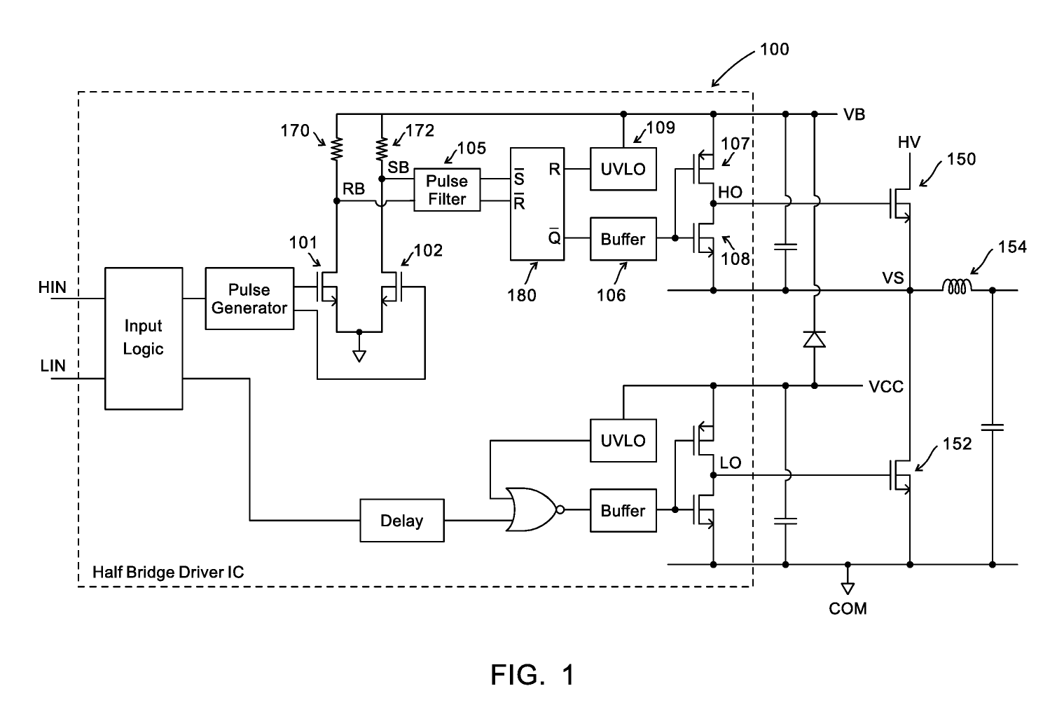

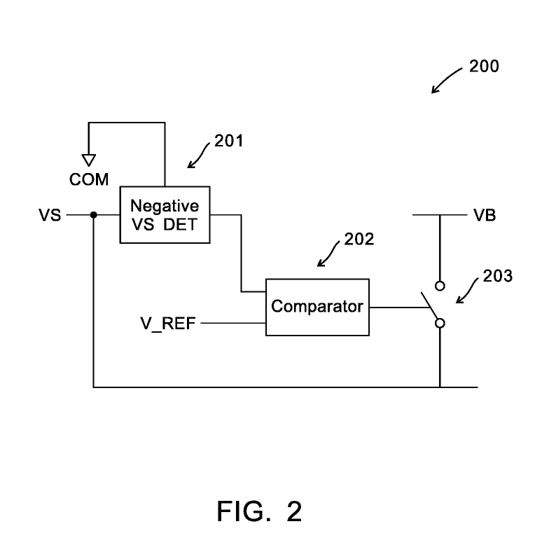

FIG. 2 shows a functional block diagram of a voltage clamping circuit 200 in one embodiment of the invention, adapted for use with or in a driver arranged to drive a half bridge circuit connected with an inductive load, such as that illustrated in FIG. 1. The voltage clamping circuit 200 is a negative transient voltage clamping circuit, and it includes a negative transient voltage detector 201, a comparator 202, and a switching device 203.

The negative transient voltage detector 201 is connected with nodes VS and COM, and is arranged to detect magnitude of negative transient voltage at node VS. The negative transient voltage detector 201 may provide an input signal indicative of the magnitude of the voltage at the switched node to the comparator 202. The input signal can be a voltage signal directly representing (with the same value as) the magnitude of the voltage at the switched node, or it may be a voltage signal indirectly (scaled, offset, etc.) representing the magnitude of the voltage at the switched node.

The comparator 202 is arranged to compare the input signal with a reference signal V_REF representing a reference clamping voltage, and to selectively control the switching device 203 based on the comparison. The reference signal V_REF representing a reference clamping voltage may be fixed, or it may be adjustable to change the reference clamping voltage. When the comparator 202 determines that the negative VS transient voltage exceeds the selected clamping voltage level, it turns on (i.e., closes) the switching device 203 connected between the nodes VB and VS to allow current to pass from node VB to node VS. This would result in the adjustment of the VS node towards positive voltage (i.e. increasing the VS voltage in the positive sense), and hence reducing the magnitude of the negative transient voltage at VS. Afterwards, when the comparator 202 determines that the negative VS transient voltage falls below the selected clamping voltage level, it turns off (i.e., opens) the switching device 203 to disconnect VS from VB. With this design, the negative transient voltage can be limited by being clamped to a selected level.

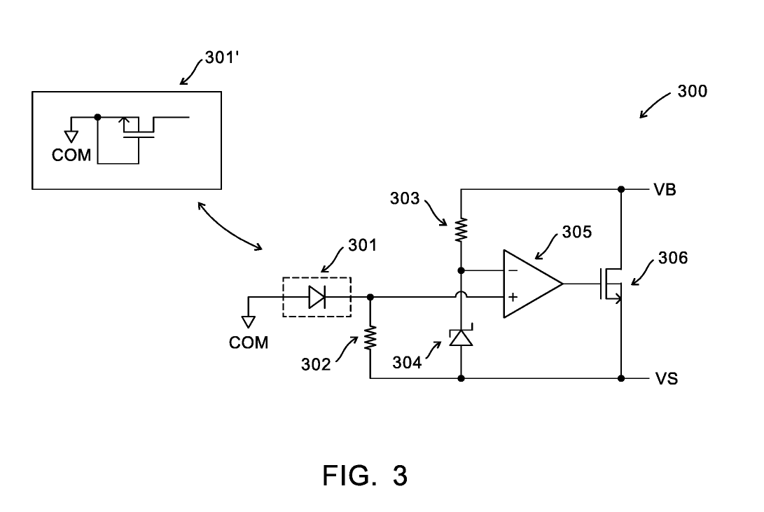

FIG. 3 shows a voltage clamping circuit 300 in accordance with one embodiment of the invention. In FIG. 3, the voltage clamping circuit 300 is a negative transient voltage clamping circuit, and it includes a negative transient voltage detector formed by diode 301 and resistor 302, a comparator 305, and a switching device 306.

The negative transient voltage detector includes a diode 301 connected between COM and a first input terminal of the comparator 305, and a resistor 302 connected between the first input terminal of the comparator 305 and VS. The diode 301 and resistor 302 are arranged to detect or monitor a magnitude of the VS transient voltage, in particular a negative VS transient voltage, and then output an input signal to be provided to the comparator 305. In one example, the diode 301 may be integrated into a half bridge driver (e.g., in the form of an IC), and it may be an emulated diode 301′ emulated using a high voltage LDMOS.

A resistor 303 and zener diode 304 are connected in series between VB and VS. The resistor 303 and the zener diode 304 are connected with a second input terminal of the comparator 305, through a node between the resistor 303 and the zener diode 304. The resistor 303 and zener diode 304 are arranged to provide a selected (or predetermined) negative VS clamping voltage. This clamping voltage may be fixed, or it may be adjustable (i.e. selectable), e.g., by choosing the zener voltage of the zener diode 304.

The comparator 305 compares the two signals received at the two input terminals, and then produces an output to selectively control operation of the switching device 306. In this example, the switching device 306 is a MOSFET, and it may be integrated into the driver or the half bridge circuit (e.g., in the form of an IC). The comparator 305 is arranged to turn on the switching device 306 (e.g., closes the MOSFET) when the comparison indicates that the magnitude of the negative transient voltage exceeds the reference voltage value so as to reduce the magnitude of the negative transient voltage at the switched node, and to turn off the switching device 306 (e.g., opens the MOSFET) when the comparison indicates that the magnitude of the negative transient voltage falls below the reference voltage value. Although not illustrated in FIG. 3, a current limiting component such as a resistor may be added to circuit, for series connection between VB and drain terminal of switching device 306, or between source terminal of switching device 306 and VS.

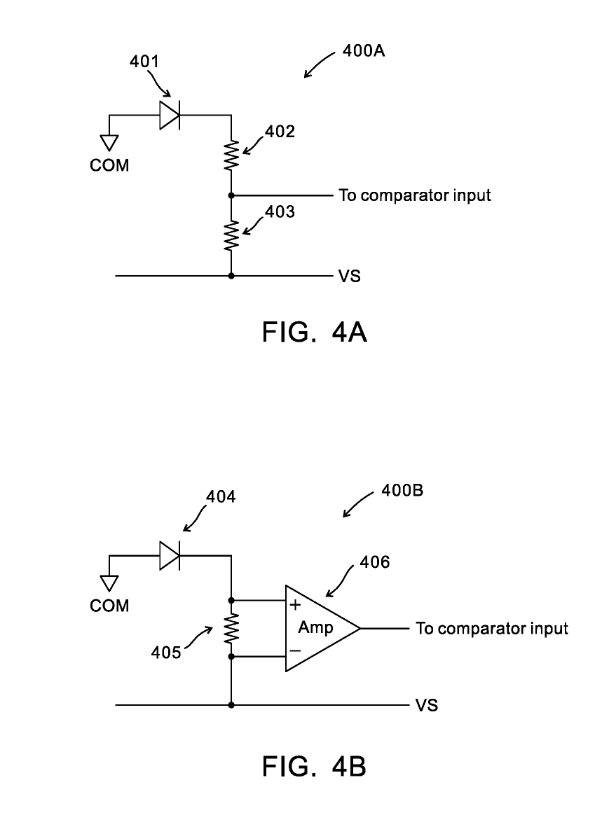

In some embodiments, the magnitude of the negative VS transient voltage detected by the detector may be scaled prior to being fed as an input signal to the comparator 305. FIGS. 4A and 4B illustrate two alternative transient voltage detectors 400A, 400B, in the form of negative transient voltage detectors, with scaling function, adapted to be used with the voltage clamping circuit 300 in FIG. 3.

The detector 400A with voltage scaling function in FIG. 4A includes a diode 401 and a potential divider formed by resistors 402 and 403 for scaling the negative VS transient voltage. The diode 401 is connected between the resistor 402 and COM. The resistors 402, 403 are connected between the diode 401 and VS; and a node between the resistors 402, 403 is arranged to be connected to the input terminal of a comparator, such as the comparator 305 of the negative transient voltage clamping circuit. The resistors 402, 403 may have the same or different resistance. The detector 400B with voltage scaling function in FIG. 4B includes a diode 404, a resistor 405, and an amplifier 406. The diode 404 is connected between the resistor 405 and COM. The resistor 405 is connected across two input terminals of the amplifier 406. The output of the amplifier 406 is connected to a comparator, such as the comparator 305 of the negative transient voltage clamping circuit.

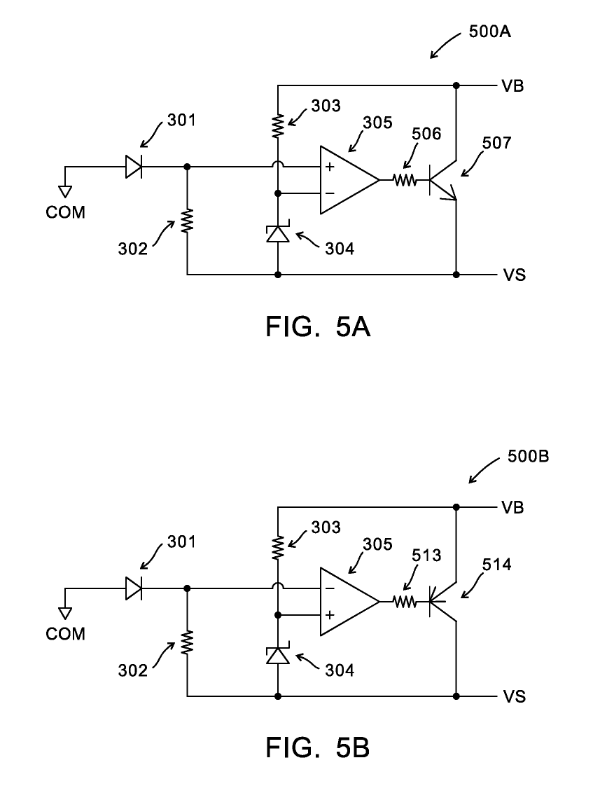

FIGS. 5A and 5B illustrate voltage clamping circuits 500A, 500B in alternative embodiments of the invention, in which the switching device 306 in the circuit of FIG. 3 is replaced with other types of switching devices. The circuits in FIGS. 5A and 5B are largely the same as that in FIG. 3, except for the arrangement of the switching device. In the following, only their differences will be described. As shown in FIGS. 5A and 5B, the switching device includes a bipolar transistor in place of a MOSFET. In FIG. 5A, the switching device is an NPN bipolar transistor 507, operably connected with a base-connected resistor 506; in FIG. 5B, the switching device is a PNP bipolar transistor 514, operably connected with a base-connected resistor 513.

Embodiments of the present invention have provided a voltage clamping circuit suitable for use in a half bridge driver. In applications where the driver is used to drive a half bridge connected with an inductive load, a negative transient voltage may occur at the output node of the half bridge. With the use of a voltage clamping circuit of the invention, it is possible to clamp the magnitude of such a transient voltage to a reference level, to ensure proper operation and operational safety of the circuit.

It will be appreciated by persons skilled in the art that numerous variations and/or modifications may be made to the invention as shown in the specific embodiments without departing from the spirit or scope of the invention as broadly described. For example, the voltage clamping circuit may be operated with any driver arranged to drive a half bridge circuit connected with an inductive load. The voltage clamping circuit need not be a negative transient voltage clamping circuit, but it can be a positive transient voltage clamping circuit. Other circuit elements operable to achieve the described function are also contemplated as falling within the ambit of the present invention. The present embodiments are, therefore, to be considered in all respects as illustrative and not restrictive.

1. A voltage clamping circuit for a driver arranged to drive a half bridge circuit connected to an inductive load, comprising:
a detector arranged to detect magnitude of a voltage at a switched node connected to the inductive load and to provide an input signal indicative of the magnitude of the voltage at the switched node; and
a comparator arranged to receive and compare the input signal to a reference signal representing a reference voltage value, for selectively controlling operation of a switching device to clamp the voltage at the switched node and reduce the magnitude of the voltage at the switched node.

2. The voltage clamping circuit of claim 1, wherein the comparator is arranged to turn on the switching device when the comparator indicates that the magnitude of the voltage at the switched node exceeds the reference voltage value, and to turn off the switching device when the comparator indicates that the magnitude of the voltage at the switched node falls below the reference voltage value.

3. The voltage clamping circuit of claim 1, wherein the reference signal is adjustable to represent different reference voltage values.

4. The voltage clamping circuit of claim 1, wherein the reference signal is fixed to represent a single reference voltage value.

5. The voltage clamping circuit of claim 1, wherein the detector comprises a diode and a resistor.

6. The voltage clamping circuit of claim 5, wherein the diode is an emulated diode emulated by a semiconductor device.

7. The voltage clamping circuit of claim 1, further comprising the switching device.

8. The voltage clamping circuit of claim 7, wherein the switching device comprises a semiconductor switch.

9. The voltage clamping circuit of claim 8, wherein the semiconductor switch comprises a MOSFET or a bi-polar transistor.

10. The voltage clamping circuit of claim 7, further comprising a current-limiting resistor connected in series with the switching device.

11. The voltage clamping circuit of claim 1, wherein the switching device is part of the driver or part of the half bridge circuit.

12. The voltage clamping circuit of claim 1, wherein the detector comprises a scaling circuit to scale the magnitude of the voltage detected at the switched node to provide the input signal.

13. The voltage clamping circuit of claim 1, wherein
the half bridge circuit comprises a high-side switching device and a low-side switching device, and
the switched node is arranged between the high-side switching device and the low-side switching device.

14. The voltage clamping circuit of claim 1, wherein
the voltage clamping circuit is a negative transient voltage clamping circuit, and
the detector is arranged to detect the magnitude of a negative transient voltage.

15. A voltage clamping method for a driver arranged to drive a half bridge circuit connected to an inductive load, the method comprising:
detecting magnitude of a voltage at a switched node connected to the inductive load and providing an input signal indicative of the magnitude of the voltage at the switched node; and
comparing the input signal to a reference signal representing a reference voltage value for selectively controlling operation of a switching device to clamp the voltage at the switched node and reduce the magnitude of the voltage at the switched node.

16. The voltage clamping method of claim 15, further comprising:
turning on the switching device when the comparing indicates that the magnitude of the voltage exceeds the reference voltage value, and turning off the switching device when the comparing indicates that the magnitude of the voltage falls below the reference voltage value.

17. The voltage clamping method of claim 15, further comprising scaling the magnitude of the voltage detected at the switched node to provide the input signal.

18. A non-transitory computer readable medium for storing computer instructions that, when executed by at least one controller or processor, causes at least one controller or processor to perform a voltage clamping method adapted for a driver arranged to drive a half bridge circuit connected with an inductive load, the method comprising: detecting a magnitude of a voltage at a switched node connected with the inductive load and to provide an input signal indicative of the magnitude of the voltage at the switched node; and comparing the input signal with a reference signal representing a reference voltage value for selectively controlling operation of a switching device to clamp the voltage at the switched node and reduce the magnitude of the voltage at the switched node.
